(19) United States
(12) Patent Application Publication
(10) Pub. No.: US 2014/0094023 A1
(43) Pub. Date: Apr. 3, 2014

(54) FABRICATING METHOD OF SEMICONDUCTOR CHIP

(71) Applicant: NATIONAL APPLIED RESEARCH LABORATORIES, Taipei City (TW)

(72) Inventors: Yao-Jen Lee, Kaohsiung (TW); Po-Jung Sung, Hsinchu (TW); Da-Wei Heh, New Taipei City (TW); Fu-Ju Hou, Hsinchu (TW); Chih-Hung Lo, Hsinchu (TW); Fu-Kuo Hsueh, Hsinchu (TW); Hsiu-Chih Chen, Hsinchu (TW)

(73) Assignee: National Applied Research Laboratories, Taipei City (TW)

(21) Appl. No.: 13/799,957

(22) Filed: Mar. 13, 2013

(30) Foreign Application Priority Data
Sep. 28, 2012 (TW) 101136018

(51) Int. Cl. H01L 21/20

(52) U.S. Cl. CPC H01L 21/2022
USPC 438/486

(57) ABSTRACT

A fabricating method of a semiconductor chip includes the following steps. Firstly, a substrate is provided, wherein an amorphous semiconductor layer is formed in a first surface of the substrate. Then, a first metal layer is formed on the amorphous semiconductor layer. Then, a thermal-treating process is performed to result in a chemical reaction between the first metal layer and a part of the amorphous semiconductor layer, thereby producing an amorphous metal semiconductor compound layer. Afterwards, a microwave annealing process is performed to recrystallize the amorphous metal semiconductor compound layer as a polycrystalline metal semiconductor compound layer.

### FIELD OF THE INVENTION

The present invention relates to a fabricating method of a semiconductor chip, and particularly to a fabricating method of a metal oxide semiconductor transistor.

### BACKGROUND OF THE INVENTION

With the miniaturization trends of the semiconductor devices in the deep submicron generation, it is an important issue to improve the device performance in the fabrication of the semiconductor devices. For example, in a metal oxide semiconductor field effect transistor (MOSFET), the dopant for activating the source/drain region, the repairing of the damaged crystal lattice structure from dopant implantation or the simultaneous formation of metal silicides on the gate structure and the source/drain region may reduce the resistance value of the semiconductor device. In other words, the activation number of the source/drain region and the resistance value of the metal silicides may influence the performance of the MOSFET.

In the conventional semiconductor manufacturing process, the activation of the source/drain region and the formation of the metal silicides should be implemented by rapid thermal annealing (RTA) processes in different temperature ranges at different time spots. Firstly, the activation of the source/drain region is performed by an ultra-high temperature annealing process at the temperature between 900° C. and 1050° C. for about 1 millisecond to 1 minute. In addition, during the process of performing the activation of the source/drain region, the crystal lattice structure is also repaired. After the crystal lattice structure is repaired, a self-aligned process is performed to form a metal silicide layer on the surface of the source/drain region. Generally, the annealing process of forming the metal silicide layer is performed by two stages. The first stage of the annealing process is carried out at the temperature between 200° C. and 300° C. The second stage of the annealing process is carried out at a temperature higher than the first stage. For example, the second stage is carried out at the temperature between 450° C. and 600° C.

From the above discussions, the conventional semiconductor manufacturing process needs three RTA processes to activate the source/drain region, repair the crystal lattice structure and form the metal silicide layer. Since the ultra-high temperature annealing process may abruptly increase the resistance value of the metal silicide layer, the two stages of the annealing process of forming the metal silicide layer should be performed after the activation of the source/drain region.

However, the conventional high temperature RTA process is detrimental to the production of the MOSFET with the size under the deep submicron. For example, the dopant of the source/drain region may easily diffuse, and the resistance value is increased. In addition, after the activation process is done, the structure of the source/drain region is restored to the orderly crystal lattice structure. As shown in FIG. 1, a metal silicide layer 5 is formed on the surface of the source/drain region 3 in the subsequent process. Since the metal silicide layer 5 may easily diffuse into the orderly crystal lattice structure of the source/drain region 3 at the high temperature, a pyramidal structure of the metal silicide layer 5 is possibly generated. Under this circumstance, it is difficult to control the thickness of the metal silicide layer 5, and a source/drain leakage current is possibly generated.

In the conventional semiconductor manufacturing process, it is impossible to repair the crystal lattice structure of the source/drain region at the ultra-high temperature after the metal silicide layer is formed. In other words, it is difficult to form an ultra-thin and low-resistance metal semiconductor compound layer by the conventional semiconductor manufacturing process.

Therefore, there is a need of providing a fabricating method of a semiconductor chip in order to eliminating the above drawbacks.

### SUMMARY OF THE INVENTION

An object of the present invention provides a fabricating method of a semiconductor chip in order to form an ultra-thin and low-resistance metal semiconductor compound layer. In addition, the purposes of activating the source/drain region and repairing the crystal lattice structure can be simultaneously achieved. Consequently, the performance of the deep submicron MOSFET will be enhanced.

An aspect of the present invention provides a fabricating method of a semiconductor chip. The fabricating method includes the following steps. Firstly, a substrate is provided, wherein an amorphous semiconductor layer is formed in a first surface of the substrate. Then, a first metal layer is formed on the amorphous semiconductor layer. Then, a thermal-treating process is performed to result in a chemical reaction between the first metal layer and a part of the amorphous semiconductor layer, thereby producing an amorphous metal semiconductor compound layer. Afterwards, a microwave annealing process is performed to recrystallize the amorphous metal semiconductor compound layer into a polycrystalline metal semiconductor compound layer.

In an embodiment, the thermal-treating process is a pre-microwave annealing process, wherein the microwave annealing process is carried out at a microwave output power higher than the pre-microwave annealing process.

In an embodiment, the pre-microwave annealing process and the microwave annealing process are carried out at a microwave frequency between 900 MHz and 150 GHz for an annealing time period between 60 seconds and 600 seconds.

In an embodiment, the pre-microwave annealing process is carried out at a microwave output power between 100 watts and 1800 watts and the microwave annealing process is carried out at a microwave output power between 1500 watts and 3500 watts while the substrate is made of silicon.

In an embodiment, the first metal layer is made of nickel or nickel alloy and the pre-microwave annealing process is carried out at a microwave output power between 100 watts and 360 watts.

In an embodiment, the pre-microwave annealing process is carried out at a microwave output power between 100 watts and 1200 watts and the microwave annealing process is carried out at a microwave output power between 1000 watts and 2800 watts while the substrate is made of germanium, gallium arsenide, or indium gallium arsenide.

In an embodiment, the first metal layer is made of nickel or nickel alloy and the pre-microwave annealing process is carried out at a microwave output power between 100 watts and 360 watts.

In an embodiment, after the thermal-treating process is performed, the chemical reaction between the first metal layer and the amorphous semiconductor layer produces the amorphous metal semiconductor compound layer with a thickness equal to or smaller than 5 nanometers. Moreover, after the microwave annealing process is performed, the amorphous metal semiconductor compound layer is recrystallized into the polycrystalline metal semiconductor compound layer with a thickness equal to or smaller than 7 nanometers.

In an embodiment, the thermal-treating process is a rapid thermal annealing process carried out for a time period between 1 second and 60 seconds.

In an embodiment, the rapid thermal annealing process is carried out at a temperature between 100° C. and 500° C. while the substrate is made of silicon.

In an embodiment, the first metal layer is made of nickel or nickel alloy and the rapid thermal annealing process is carried out at a temperature between 100° C. and 220° C.

In an embodiment, the rapid thermal annealing process is carried out at a temperature between 100° C. and 450° C. while the substrate is made of germanium, gallium arsenide, or indium gallium arsenide.

In an embodiment, the first metal layer is made of nickel or nickel alloy and the rapid thermal annealing process is carried out at a temperature between 100° C. and 220° C.

In an embodiment, the polycrystalline metal semiconductor compound layer has a resistance value lower than 50 ohms/sq.

In an embodiment, the first metal layer is made of palladium, platinum, dysprosium, tantalum, ytterbium, nickel, titanium, cobalt, tungsten, or an alloy thereof.

In an embodiment, after the microwave annealing process is performed, the fabricating method further comprises a step of recrystallizing a partial amorphous semiconductor layer which is not reacted with the first metal layer into a monocrystalline semiconductor layer.

In an embodiment, before the thermal-treating process is performed, the fabricating method further comprises a step of forming a second metal layer on the first metal layer, so that the second metal layer is protected by the first metal layer.

In an embodiment, during the microwave annealing process is performed, a first susceptor and a second susceptor are disposed over the first surface and a second surface of the substrate, respectively.

In an embodiment, the second susceptor over the second surface of the substrate is in direct contact with the substrate.

In an embodiment, the first susceptor over the first surface of the substrate is located near the substrate and separated from the substrate.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating the formation of a pyramidal structure of the metal silicide layer in the conventional MOSFET;

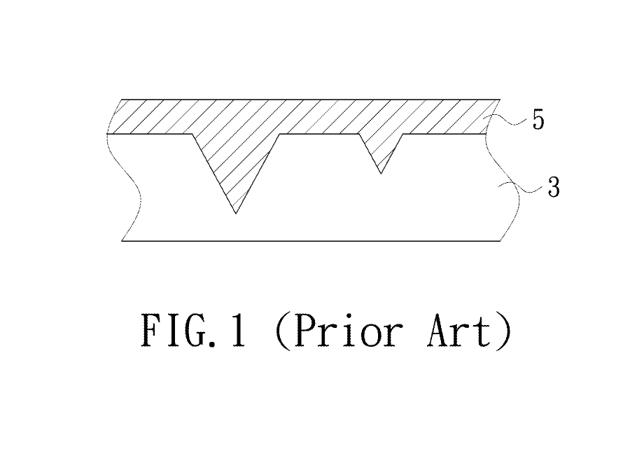

FIGS. 2A˜2F are schematic cross-sectional views illustrating a fabricating method of a semiconductor chip according to an embodiment of the present invention;

FIG. 3 is a schematic side view illustrating the arrangement of susceptors in a microwave annealing machine for facilitating the high-power microwave annealing process according to an embodiment of the present invention; and

FIG. 4 is a schematic side view illustrating the arrangement of susceptors in a microwave annealing machine for facilitating the high-power microwave annealing process according to another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

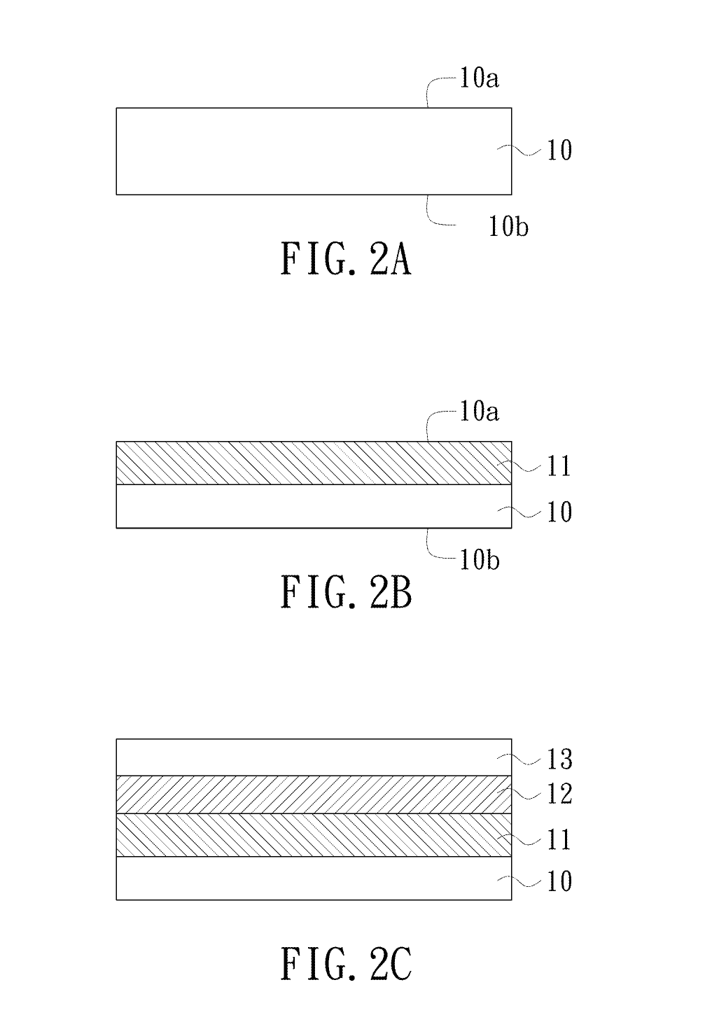

The present invention provides a fabricating method of a small-sized semiconductor chip. For example, the small-sized semiconductor chip is a deep submicron MOSFET. FIGS. 2A˜2F are schematic cross-sectional views illustrating a fabricating method of a semiconductor chip according to an embodiment of the present invention.

Firstly, as shown in FIG. 2A, a substrate 10 is provided. The substrate 10 is made of indium gallium arsenide, gallium arsenide, pure silicon, silicon germanium, carbon-doped silicon, phosphor-doped silicon, boron-doped silicon, carbon-doped germanium or tin-doped germanium. In addition, the substrate 10 has a monocrystalline structure.

Then, an ion implantation process is performed to dope a first surface 10a of the substrate 10 with a conductive dopant in order to form a P-type doped region or an N-type doped region of a source/drain region. The conductive dopant is a Group-III element or a Group-VI element. The hitting energy and the dopant concentration in the ion implantation process are sufficient to result in amorphization of the surface of the substrate 10 and destroy the monocrystalline structure of the substrate 10. Consequently, an amorphous semiconductor layer 11 is formed in the first surface 10a of the substrate 10.

As previously described in the prior art, after the amorphous semiconductor layer is formed, an ultra-high temperature RTA process will be performed to activate the source/drain region and repair the amorphous semiconductor layer as the monocrystalline structure. The fabricating method of the present invention is distinguished from the conventional method because the steps of activating the source/drain region and repairing the crystal lattice structure are omitted. On the other hand, as shown in FIG. 2C, a first metal layer 12 is directly deposited on the amorphous semiconductor layer 11 by performing a physical vapor deposition (PVD) process or using an E-Gun evaporation system. The first metal layer 12 is made of palladium, platinum, dysprosium, tantalum, ytterbium, nickel, titanium, cobalt, tungsten, or an alloy thereof. The deposition thickness of the first metal layer 12 is about 15 nanometers. Then, for protecting the first metal layer 12 in the subsequent process, a second metal layer 13 is deposited on the first metal layer 12. The second metal layer 13 is made of titanium or titanium nitride. The deposition thickness of the second metal layer 13 is about 15 nanometers.

Then, a metal semiconductor compound layer is formed by a two-stage annealing process. The first stage of the two-stage annealing process is a low-power microwave annealing process. The low-power microwave annealing process is carried out at a microwave frequency between 900 MHz and 150 GHz for an annealing time period between 60 seconds and 600 seconds. In the first stage of the two-stage annealing process, the low-power microwave radiation energy may cause a chemical reaction between the first metal layer 12 and the amorphous semiconductor layer 11. Consequently, an amorphous metal semiconductor compound layer 20 is produced (see FIG. 2D). The amorphous metal semiconductor compound layer 20 is a reaction product of the material of the first metal layer 12 and the material of the substrate 10. For example, the amorphous metal semiconductor compound layer 20 is an amorphous nickel silicide (NiSi) layer, an amorphous nickel silicon germanium compound (NiSiGe) layer, an amorphous nickel indium gallium arsenide (Ni—InGaAs) layer, an amorphous nickel gallium arsenide (Ni—GaAs) layer or an amorphous titanium silicide layer.

The range of the microwave output power may be varied according to the material of the substrate 10 and the material of the first metal layer 12. In an embodiment, in a case the substrate 10 is made of silicon, e.g. pure silicon, silicon germanium, carbon-doped silicon, phosphor-doped silicon, or boron-doped silicon, the low-power microwave annealing process may be carried out at a microwave output power between 100 watts and 1800 watts. If the first metal layer is made of nickel or nickel alloy, the low-power microwave annealing process may be carried out at a lower microwave output power, such as between 100 watts and 360 watts.

In an embodiment, in a case the substrate 10 is made of germanium, e.g. carbon-doped germanium or tin-doped germanium, or gallium arsenide, indium gallium arsenide, the low-power microwave annealing process may be carried out at a microwave output power between 100 watts and 1200 watts. Likewise, if the first metal layer is made of nickel or nickel alloy, the low-power microwave annealing process may be carried out at a lower microwave output power, such as between 100 watts and 360 watts.

Since the first stage of the two-stage annealing process is used to form the amorphous metal semiconductor compound layer 20, low energy is sufficient. In another embodiment, the first stage of the two-stage annealing process is a rapid thermal annealing (RTA) process carried out for 1˜60 seconds. The RTA process may cause a chemical reaction between the first metal layer 12 and the amorphous semiconductor layer 11. Similarly, the amorphous metal semiconductor compound layer 20 is a reaction product of the material of the first metal layer 12 and the material of the substrate 10.

The range of the temperature of the RTA process may be varied according to the material of the substrate 10 and the material of the first metal layer 12. In an embodiment, the RTA process may be carried out at a temperature between 100° C. and 500° C. while the substrate 10 is made of silicon. If the first metal layer is made of nickel or nickel alloy, the RTA process may be carried out at a lower temperature, such as between 100° C. and 220° C.

In an embodiment, the RTA process may be carried out at a temperature between 100° C. and 450° C. while the substrate 10 is made of germanium, gallium arsenide, or indium gallium arsenide. If the first metal layer is made of nickel or nickel alloy, the RTA process may be carried out at a lower temperature, such as between 100° C. and 220° C.

It in noted that the process of forming the amorphous metal semiconductor compound layer 20 is performed before the activation of the source/drain region. That is, during the process of forming the amorphous metal semiconductor compound layer 20 is performed, the crystal lattice structure of the amorphous semiconductor layer 11 in contact with the amorphous metal semiconductor compound layer 20 is disordered. The disordered crystal lattice structure of the amorphous semiconductor layer 11 may hinder the metal semiconductor compound from diffusing into the source/drain region in order to prevent formation of the pyramidal structure. Consequently, an ultra-thin amorphous metal semiconductor compound layer 20 can be obtained. For example, the amorphous metal semiconductor compound layer 20 is an amorphous metal silicide layer with a thickness equal to or smaller than about 5 nanometers or an amorphous metal germanide layer with a thickness equal to or smaller than about 4.5 nanometers.

After the first stage of the two-stage annealing process is performed, a part of the unreacted amorphous semiconductor layer 11 and a part of the unreacted first metal layer 12 are remained. Then, an etching process (e.g. a wet etching process) is performed to remove the unreacted first metal layer 12 and the protective layer (i.e. the second metal layer). The resulting structure is shown in FIG. 2E.

Then, the second stage of the two-stage annealing process is performed. The second stage of the two-stage annealing process is a high-power microwave annealing process for recrystallizing the amorphous metal semiconductor compound layer 20 into a polycrystalline metal semiconductor compound layer 30. In an embodiment, while the substrate 10 is made of silicon, the high-power microwave annealing process is carried out at a microwave output power between 1500 watts and 3500 watts and at a microwave frequency between 900 MHz and 150 GHz for an annealing time period between 60 seconds and 600 seconds. In the second stage of the two-stage annealing process, the high-power microwave radiation energy is able to recrystallize the amorphous metal semiconductor compound layer 20 into the polycrystalline metal semiconductor compound layer 30. For example, the polycrystalline metal semiconductor compound layer 30 is a polycrystalline metal silicide layer with a thickness of equal to or smaller than about 7 nanometers.

The range of the microwave output power may be varied according to the material of the substrate 10. For example, in a case that the substrate 10 is made of germanium, indium gallium arsenide or gallium arsenide, the high-power microwave annealing process is preferably carried out at a microwave output power between 1000 watts and 2800 watts. Under this circumstance, the polycrystalline metal semiconductor compound layer 30 is a polycrystalline metal indium gallium arsenide layer or a polycrystalline metal gallium arsenide layer with a thickness of equal to or smaller than about 6.5 nanometers.

Please refer to FIG. 2E and FIG. 2F. Due to the high-power microwave radiation energy, a lower system temperature, which is equal to the temperature of a semiconductor chip under the high-power microwave radiation energy, is sufficient to simultaneously achieve the functions of activating the source/drain region and repairing the damaged crystal lattice structure of the amorphous semiconductor layer 11. Consequently, the crystal lattice structure of the amorphous semiconductor layer 11 is restored to the original monocrystalline structure of the substrate 10. For example, the lower system temperature for silicon substrate ranges between 450° C. and 550° C. and for the other substrates range between 350° C.˜450° C.

Furthermore, since it is not necessary to activate the source/drain region by the conventional ultra-high temperature annealing process, the resistance value of the metal semiconductor compound layer is no longer abruptly increased. It is preferred that the resistance value of the polycrystalline metal semiconductor compound layer 30 is lower than 50 ohms/sq. Moreover, due to the lower system temperature, the molecules of the metal semiconductor compound layer will not be suffered from serious vibration, and the possibility of diffusing the molecules of the metal semiconductor compound layer into the source/drain region will be minimized. Under this circumstance, the pyramidal structure of the metal semiconductor compound layer in not formed, and the source/drain leakage current is not generated. Consequently, the thickness of the polycrystalline metal semiconductor compound layer 30 can be controlled more easily, and the polycrystalline metal semiconductor compound layer 30 is an ultra-thin and low-resistance metal semiconductor compound layer.

However, in a case that the semiconductor chip is placed within a microwave annealing machine to be treated by the high-power microwave annealing process, the resistance value of the polycrystalline metal semiconductor compound layer is not uniformly distributed. In other words, the fabricating method of the semiconductor chip needs to be further improved.

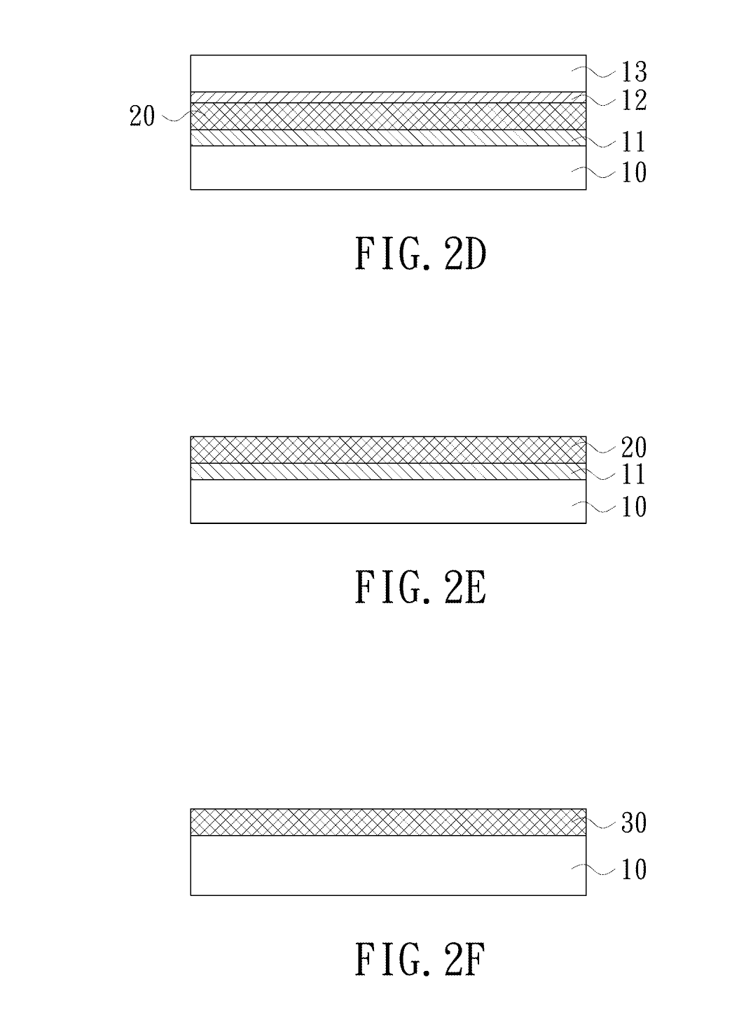

FIG. 3 is a schematic side view illustrating the arrangement of susceptors in a microwave annealing machine for facilitating the high-power microwave annealing process according to an embodiment of the present invention. As shown in FIG. 3, when the semiconductor chip is placed within the microwave annealing machine, two susceptors 40a and 40b are disposed over the first surface 10a and a second surface 10b of the substrate 10, respectively. In this embodiment, the two susceptors 40a and 40b are separated from the first surface 10a and the second surface 10b of the substrate 10, respectively. For example, the susceptors 40a and 40b are quartz plates or glass plates for facilitating uniformly conducting heat without absorbing the microwave radiation energy, so that the resistance value of the polycrystalline metal semiconductor compound layer 30 is distributed more uniformly.

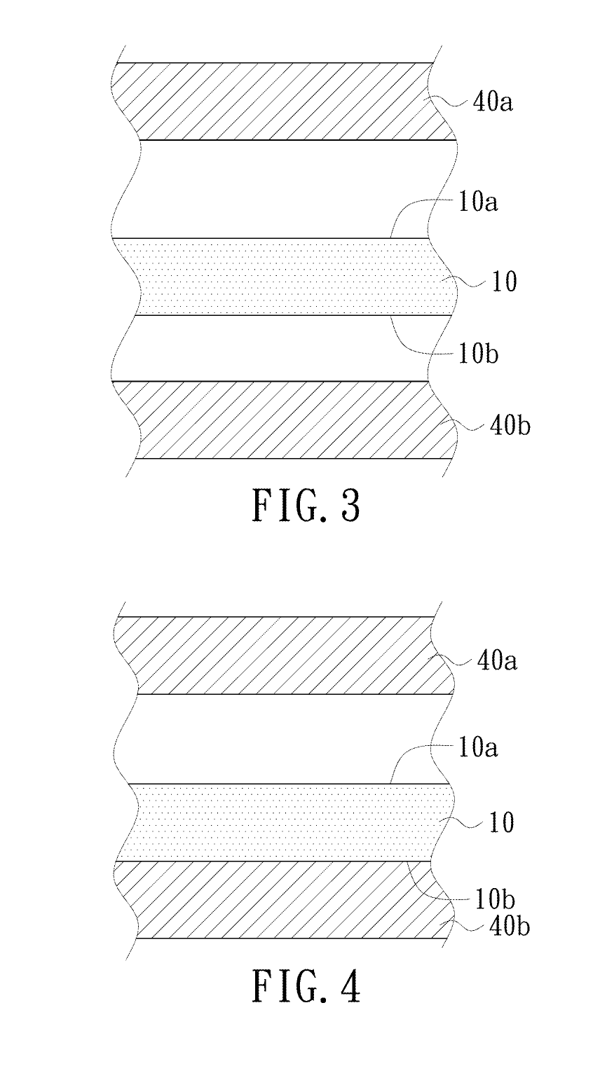

FIG. 4 is a schematic side view illustrating the arrangement of susceptors in a microwave annealing machine for facilitating the high-power microwave annealing process according to another embodiment of the present invention. In this embodiment, two susceptors 40a and 40b are disposed over the first surface 10a and the second surface 10b of the substrate 10, respectively. Moreover, the susceptor 40a is located near the first surface 10a of the substrate 10, and separated from the first surface 10a of the substrate 10; but the susceptor 40b is in direct contact with the second surface 10b of the substrate 10. Consequently, the uniformity of the resistance value of the polycrystalline metal semiconductor compound layer 30 can be largely enhanced by about 50%. Moreover, during the first stage of the two-stage annealing process, the microwave annealing machine can be also equipped with the susceptors such as quartz plates or glass plates.

From the above descriptions, the present invention provides a fabricating method of a semiconductor chip. Before the damaged crystal lattice structure of the amorphous semiconductor layer is repaired, a two-stage high-power microwave annealing process is performed. Consequently, the fabricating method is simplified, and the drawback of generating the source/drain leakage current is solved. Moreover, the use of the fabricating method of the present invention is effective to form an ultra-thin and low-resistance polycrystalline metal semiconductor compound layer. In addition, the purposes of activating the source/drain region and repairing the crystal lattice structure are achievable. Consequently, the performance of the deep submicron MOSFET will be enhanced

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A fabricating method of a semiconductor chip, the fabricating method comprising steps of:
providing a substrate, wherein an amorphous semiconductor layer is formed in a first surface of the substrate;
forming a first metal layer on the amorphous semiconductor layer;
performing a thermal-treating process to result in a chemical reaction between the first metal layer and a part of the amorphous semiconductor layer, thereby producing an amorphous metal semiconductor compound layer; and
performing a microwave annealing process to recrystallize the amorphous metal semiconductor compound layer into a polycrystalline metal semiconductor compound layer.

2. The fabricating method according to claim 1, wherein the thermal-treating process is a pre-microwave annealing process, the microwave annealing process carried out at a microwave output power higher than the pre-microwave annealing process.

3. The fabricating method according to claim 2, wherein the pre-microwave annealing process and the microwave annealing process are carried out at a microwave frequency between 900 MHz and 150 GHz for an annealing time period between 60 seconds and 600 seconds.

4. The fabricating method according to claim 2, wherein the pre-microwave annealing process is carried out at a microwave output power between 100 watts and 1800 watts and the microwave annealing process is carried out at a microwave output power between 1500 watts and 3500 watts while the substrate is made of silicon.

5. The fabricating method according to claim 4, wherein the first metal layer is made of nickel or nickel alloy and the pre-microwave annealing process is carried out at a microwave output power between 100 watts and 360 watts.

6. The fabricating method according to claim 2, wherein the pre-microwave annealing process is carried out at a microwave output power between 100 watts and 1200 watts and the microwave annealing process is carried out at a microwave output power between 1000 watts and 2800 watts while the substrate is made of germanium, gallium arsenide, or indium gallium arsenide.

7. The fabricating method according to claim 6, wherein the first metal layer is made of nickel or nickel alloy and the pre-microwave annealing process is carried out at a microwave output power between 100 watts and 360 watts.

8. The fabricating method according to claim 1, wherein the thermal-treating process is a rapid thermal annealing process carried out for a time period between 1 second and 60 seconds.

9. The fabricating method according to claim 8, wherein the rapid thermal annealing process is carried out at a temperature between 100° C. and 500° C. while the substrate is made of silicon.

10. The fabricating method according to claim 9, wherein the first metal layer is made of nickel or nickel alloy and the rapid thermal annealing process is carried out at a temperature between 100° C. and 220° C.

11. The fabricating method according to claim 8, wherein the rapid thermal annealing process is carried out at a temperature between 100° C. and 450° C. while the substrate is made of germanium, gallium arsenide, or indium gallium arsenide.

12. The fabricating method according to claim 11, wherein the first metal layer is made of nickel or nickel alloy and the rapid thermal annealing process is carried out at a temperature between 100° C. and 220° C.

13. The fabricating method according to claim 1, wherein after the thermal-treating process is performed, the chemical reaction between the first metal layer and the amorphous semiconductor layer produces the amorphous metal semiconductor compound layer with a thickness equal to or smaller than 5 nanometers, wherein after the microwave annealing process is performed, the amorphous metal semiconductor compound layer is recrystallized into the polycrystalline metal semiconductor compound layer with a thickness equal to or smaller than 7 nanometers.

14. The fabricating method according to claim 1, wherein the first metal layer is made of palladium, platinum, dysprosium, tantalum, ytterbium, nickel, titanium, cobalt, tungsten, or an alloy thereof.

15. The fabricating method according to claim 1, wherein the polycrystalline metal semiconductor compound layer has a resistance value lower than 50 ohms/sq.

16. The fabricating method according to claim 1, wherein after the microwave annealing process is performed, the fabricating method further comprises a step of recrystallizing a partial amorphous semiconductor layer which is not reacted with the first metal layer into a monocrystalline semiconductor layer.

17. The fabricating method according to claim 1, wherein before the thermal-treating process is performed, the fabricating method further comprises a step of forming a second metal layer on the first metal layer, so that the second metal layer is protected by the first metal layer.

18. The fabricating method according to claim 1, wherein during the microwave annealing process is performed, a first susceptor and a second susceptor are disposed over the first surface and a second surface of the substrate, respectively.

19. The fabricating method according to claim 18, wherein the second susceptor over the second surface of the substrate is in direct contact with the substrate.

20. The fabricating method according to claim 18, wherein the first susceptor over the first surface of the substrate is located near the substrate and separated from the substrate.
